(19) United States
(12) Patent Application Publication
(10) Pub. No.: US 2012/0268296 A1
(43) Pub. Date: Oct. 25, 2012

(54) INPUT DEVICE AND INPUT / OUTPUT DEVICE

(76) Inventors: Keizo Morikawa, Tokyo (JP); Lidong Zhao, Dalian (CN)

(21) Appl. No.: 13/387,375

(22) PCT Filed: Aug. 22, 2011
(86) PCT No.: PCT/JP2011/068878

§ 371 Date: Jan. 27, 2012

(30) Foreign Application Priority Data
Aug. 23, 2010 (JP) 2010-186085

(51) Int. Cl. H03K 17/94

(52) U.S. Cl. 341/22

(57) ABSTRACT

The present invention provides an input device and an input/output device that can realize facilitation of input work and systematization of a combination of detection information of the ON state or the OFF state of switches.
In an input device that has a switch unit (3) including plural temporary input switches (1) and plural actual input switches (2), a detection information generating unit (4) detecting the ON state or the OFF state of each temporary input switch and each actual input switch of the switch unit, combining detected information (7), and generating combined detection information (8), a storage unit (5) storing data (9) corresponding to each combined detection information, and an input determining unit (6) acquiring the combined detection information from the detection information generating unit, associating the acquired combined detection information with data stored in the storage unit, and determining data to be input, and concludes the combination of the detection information only when the detection information generating unit detects the ON state of any actual input switch and detects simultaneous turning-off of all of the actual input switches, the number of each of the temporary input switches and the actual input switches of the switch unit is equalized and the temporary input switches and the actual input switches are disposed so as to be symmetric with respect to a line.

### TECHNICAL FIELD

The present invention relates to an input device for inputting data of, for example, letters to various kinds of computers and an input/output device configured by adding an output means to the input device.

### BACKGROUND ART

In inputting data to various kinds of computers in the related art, development of a device or a method for inputting enormous data of, for example, letters, figures, and symbols by using a minimum number of switches has been tried.

The following Patent Literature 1 discloses an input device that limits the number of switches to be included and realizes an input of the enormous data by a combination of an ON state or an OFF state of the limited switches.

Specifically, Patent Literature 1 discloses the input device that detects the ON or the OFF state of each switch during a period from the detection of simultaneous turning-off of all of the switches included in the input device to the next detection of simultaneous turning-off of all of the switches, combines detection information to generate combined detection information, and determines which data is input on the basis of the combined detection information.

That is, the input device finally determines a combination of the ON or the OFF state of each switch with the simultaneous turning-off of all of the switches, generates the combined detection information, and determines the input data on the basis of the combined detection information.

### CITATION LIST

### Patent Literature

Patent Literature 1: Japanese Patent Application Laid-Open No. 64-8425

### DISCLOSURE OF INVENTION

### Problem to be Solved by the Invention

However, In Patent Literature 1, the determination regarding the combined detection information that determines the input data is triggered by the detection of the simultaneous turning-off, and the objects of the simultaneous turning-off correspond to all of the switches. Accordingly, after a turning-on operation of any switch is performed to start input work, at least one switch needs to be held at an ON position until the input work ends. As a result, the input work is complicated.

Since the combined detection information is generated by a combination of the ON state or the OFF state of each switch of one system, it is difficult to systematize the combined detection information.

### Means for Solving Problem

In order to resolve the above problem radically, the present invention provides an input device and an input/output device that include temporary input switches to be excluded from objects of simultaneous turning-off and are capable of enabling easy input work and systematization of combined detection information by adding independent combinations of the ON state or the OFF state not bounded by simultaneous turning-off of the temporary input switches.

In summary, an input device according to the present invention includes: a switch unit that includes a plurality of temporary input switches and a plurality of actual input switches; a detection information generating unit that detects an ON state or an OFF state of each temporary input switch and each actual input switch of the switch unit, combines detected information, and generates combined detection information; a storage unit that stores data corresponding to each combined detection information; and an input determining unit that acquires the combined detection information from the detection information generating unit, associates the acquired combined detection information with data stored in the storage unit, and determines data to be input, wherein the combination of the detection information is determined only when the detection information generating unit detects the ON state of any actual input switch and detects simultaneous turning-off of all of the actual input switches.

Further, the number of each of the temporary input switches and the actual input switches of the switch unit is equalized and the temporary input switches and the actual input switches are disposed so as to be symmetric with respect to a line.

An input/output device according to the present invention includes: an input unit that has a switch unit that includes a plurality of temporary input switches and a plurality of actual input switches to be the same number and to be disposed so as to be in line target, a plurality of operation units that reciprocally move between the temporary input switches and the actual input switches of the switch unit to be disposed so as to be in line target and perform the turning-on/turning-off operations on the temporary input switches and the actual input switches, a detection information generating unit that detects the ON state or the OFF state of each temporary input switch and each actual input switch of the switch unit, combines detected information, and generates combined detection information, a storage unit that stores data corresponding to each combined detection information, and an input determining unit that acquires the combined detection information from the detection information generating unit, associates the combined detection information with the data stored in the storage unit, and determines data to be input, and determines the combination of the detection information only when the detection information generating unit detects the ON state of any actual input switch and detects simultaneous turning-off of all of the actual input switches.

Further, the input/output device according to the present invention includes: an output unit that has an output rotation shaft that performs left rotation, right rotation, rotation stop about an axis line crossing a ventral surface of a fingertip of an operator in each operation unit, an output determining unit that acquires data from the outside, associates the data with the data stored in the storage unit, and determines the combined detection information to be output, a rotation information generating unit that generates rotation information of the output rotation shaft from the combined detection information acquired from the output determining unit, and a rotation power unit that acquires the rotation information from the rotation information generating unit and causes the left rotation, the right rotation, and the rotation stop of the output rotation shaft, wherein the rotation information generating unit generates rotation information of one of the left and right rotations from the turning-on detection information of the temporary input switches in the combined detection information, generates rotation information of the other one of the left and right rotations from the turning-on detection information of the actual input switches, generates rotation information of the rotation stop from turning-off detection information of the temporary input switches, generates rotation information of the rotation stop from turning-off detection information of the actual input switches, generates rotation information of simultaneous rotation stop of all of output rotation shafts from simultaneous turning-off detection information of all of the actual input switches, and generates the rotation information.

In the input/output device according to the present invention, preferably, an uneven portion that raises a sense of touch with a ventral surface of a fingertip of an operator is formed on a front end face of the output rotation shaft, and the uneven portion is formed such that the shape of a rotation stop state of the output rotation shaft and the shape of a state in which the output rotation shaft is rotated by 1/n to the left side from the rotation stop state become the same and the shape of the rotation stop state and the shape of a state in which the output rotation shaft is rotated by 1/n to the right side from the rotation stop state become the same.

### Effect of the Invention

Therefore, the input device and the input/output device according to the present invention include the temporary input switches to be excluded from the simultaneous turning-off objects in addition to the actual input switches to be the simultaneous turning-off objects, the combination of the ON state or the OFF state of the temporary input switches is added to the combination of the ON state or the OFF state of the actual input switches, and combinations of the ON state or the OFF state of the switches of independent two systems can be realized.

The combined detection information can be easily systematized using the combinations of the two systems.

For this reason, the enormous data can be input by the switch operation divided into two stages, the input work can be significantly facilitated, and the acquisition of the data can also be facilitated. For example, if the combination of the ON state or the OFF state of the temporary input switches is allocated to consonant data and the combination of the ON state or the OFF state of the actual input switches is allocated to vowel data, the letter input work and the acquisition of the data can be significantly facilitated.

Further, with a configuration in which the number of the temporary input switches is equal to the number of the actual input switches of the switch unit and the temporary input switches and the actual input switches are symmetrically disposed with respect to a line, the operations of the switches of the two systems, that is, the temporary input switches and the actual input switches can be distinguishably performed, which reduces the load on the operator.

The input/output device according to the present invention can convert the systematized combined detection information into the rotation information, perform the left rotation, the right rotation, or the rotation stop of the output rotation shaft according to the rotation information, output the data, and systematize an output, similarly to the input.

Further, the operator can clearly recognize the number of left and right rotations or the rotation stop of the output rotation shaft by the uneven portion formed on the front end face of the output rotation shaft and can recognize the left rotation, the right rotation, or the rotation stop by only 1/n rotation of the output rotation shaft.

### BRIEF DESCRIPTION OF DRAWINGS

FIG. 1 is a diagram illustrating an arrangement of temporary input switches and actual input switches in a switch unit of an input device according to the present invention.

FIG. 2 is a schematic diagram illustrating a configuration of the input device according to the present invention.

FIG. 3 is a flowchart illustrating an input process of the input device according to the present invention.

FIG. 4 is a diagram illustrating operation symbols.

FIG. 5 is a diagram illustrating a data table listing the operation symbols.

FIG. 6 is a diagram illustrating a data table listing the operation symbols that are rotated by 90 degrees in a clockwise direction.

FIG. 7 is a schematic diagram illustrating a usage example where the input device according to the present invention is used together with a keyboard.

FIG. 8(A) is a diagram illustrating an arrangement of the temporary input switches, the actual input switches, and the operation units of an input/output device according to the present invention in plan view and FIG. 8(B) is a diagram illustrating the arrangement of the temporary input switch, the actual input switch, and the operation unit in side view.

FIG. 9 is a schematic diagram illustrating a configuration of the input/output device according to the present invention.

FIGS. 10(A) to 10(D) are diagrams illustrating an uneven form of the front end face of an output rotation shaft.

FIG. 11(A) is a diagram illustrating a change from operation symbols to tactile symbols and FIG. 11(B) is a comparative view of the tactile symbols and the operation symbols.

FIG. 12 is a diagram illustrating a data table listing the tactile symbols and the operation symbols in parallel.

FIG. 13 is a schematic diagram illustrating a usage example of the input/output device according to the present invention.

### BEST MODE(S) FOR CARRYING OUT THE INVENTION

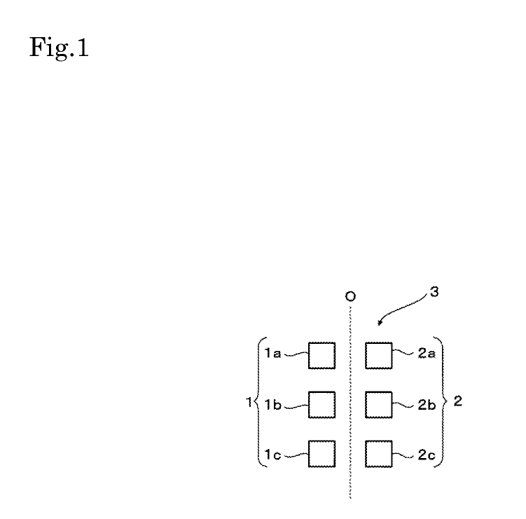

Hereinafter, best modes for carrying out the present invention will be described on the basis of FIGS. 1 to 13.

First, an input device according to the present invention will be described on the basis of FIGS. 1 to 7.

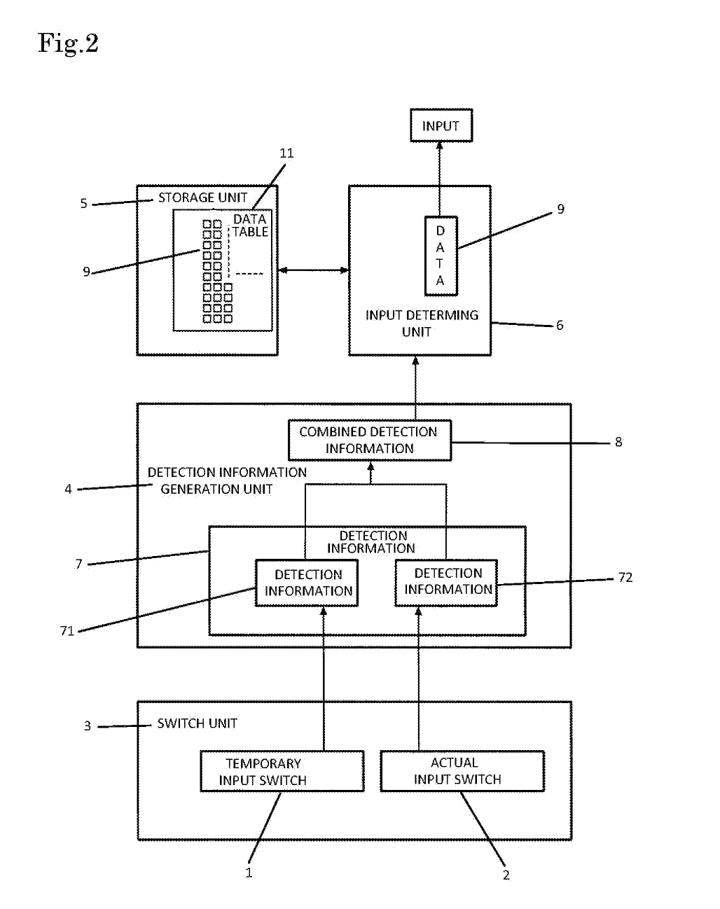

As illustrated in FIGS. 1 and 2, the input device according to the present invention basically has a switch unit 3 that includes temporary input switches 1 and actual input switches 2, a detection information generating unit 4 that detects the ON state or the OFF state of each temporary input switch 1 and each actual input switch 2 of the switch unit 3, combines detected information 7, and generates combined detection information 8, a storage unit 5 that stores data 9 corresponding to each combined detection information 8, and an input determining unit 6 that acquires the combined detection information 8 from the detection information generating unit 4, associates the combined detection information 8 with the data 9 stored in the storage unit 5, and determines the data 9 to be input. Similarly to a known keyboard, in the input device, the switch unit 3 is disposed on the surface side of a casing and the detection information generating unit 4, the storage unit 5, and the input determining unit 6 are disposed on the inner side of the casing.

Similarly to a known key switch, the temporary input switches 1 and the actual input switches 2 that are included by the switch unit 3 reciprocally move between the turning-off position of the upper limit and the turning-on position of the lower limit. The temporary input switches 1 and the actual input switches 2 are held at the turning-off position by an elastic biasing unit at the time of a normal operation and move to the turning-on position at the time of a pressing operation. If the pressing state is released, the temporary input switches 1 and the actual input switches 2 are automatically returned to the turning-off position by the elastic biasing unit.

The temporary input switches 1 and the actual input switches 2 are not limited to the above form. If the temporary input switches 1 and the actual input switches 2 can be freely moved between the turning-on position and the turning-off position, the temporary input switches 1 and the actual input switches 2 may take an arbitrary form according to the implementation.

The three temporary input switches 1 (1a, 1b, and 1c) are provided in one vertical line, the three actual input switches (2a, 2b, and 2c) are provided in one vertical line, and the temporary input switches 1 and the actual input switches 2 are line-symmetrically disposed with respect to a object axis O.

In the invention, the number of the temporary input switches 1 and the number of the actual input switches 2 are not limited to three, and both of the input switches 1 and 2 may be plural and the same number. Both of the input switches 1 and 2 may be disposed symmetrically with respect to line and arrangements other than one vertical line are not excluded for its arrangement.

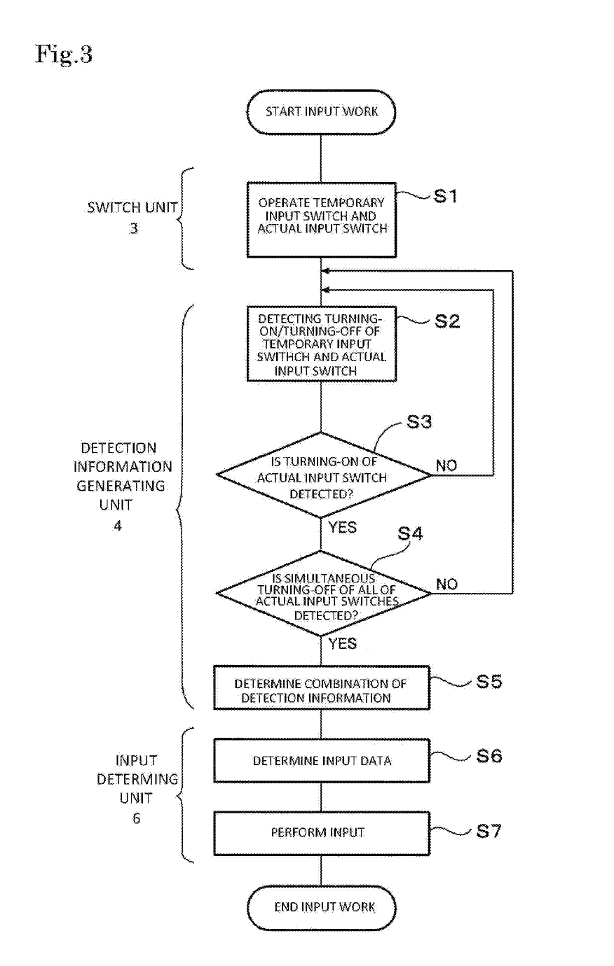

As illustrated in FIGS. 2 and 3, the detection information generating unit 4 detects the ON state or the OFF state of each temporary input switch 1 to generate detection information 71 (detection information 7), and detects the ON state or the OFF state of each actual input switch 2 to generate detection information 72 (detection information 7). Then, when the detection information generating unit 4 detects simultaneous turning-off of all of the actual input switches 2 after detecting the ON state of any actual input switch 2, the detection information generating unit 4 determines a combination of the detection information 71 and the detection information 72 and generates the combined detection information 8.

That is, only when the detection information generating unit 4 detects the ON state of any actual input switch 2 and then detects simultaneous turning-off of all of the actual input switches 2, the detection information generating unit 4 determines the combination of the detection information 71 and the detection information 72 and generates the combined detection information 8, and excludes the temporary input switches 1 from simultaneous turning-off objects.

For this reason, the combination of the ON state or the OFF state of the temporary input switches 1 is added to the combination of the ON state or the OFF state of the actual input switches 2 and combinations of the ON state or the OFF state of independent two systems of the switches can be realized. As a result, the enormous data 9 can be input by a switch operation divided into two steps, the input work can be easily performed, and the data can be easily acquired.

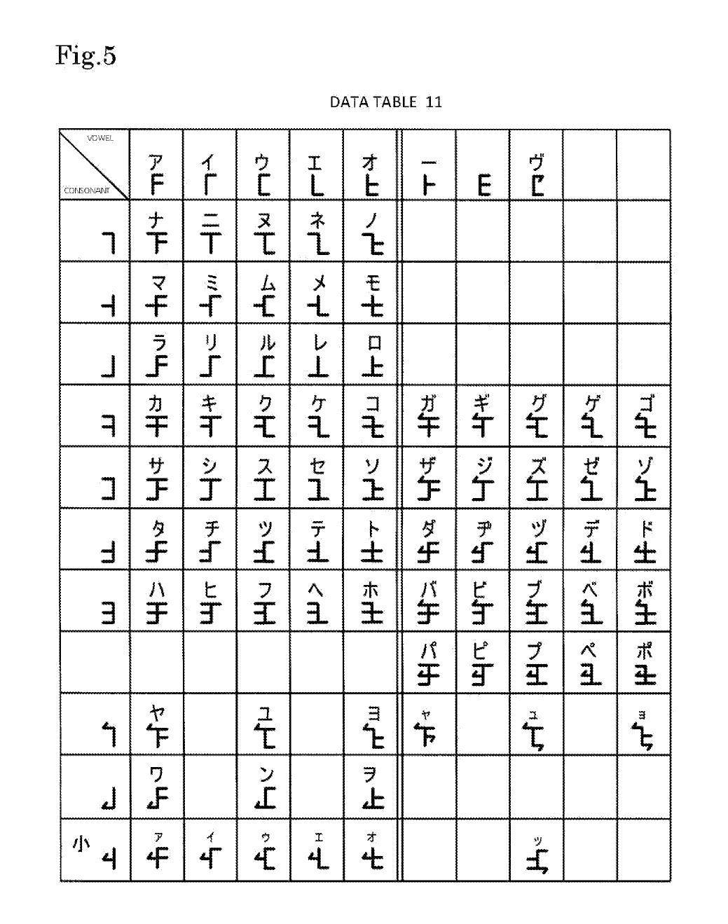

The storage unit 5 stores the data 9 that corresponds to each combined detection information 8. For example, the storage unit 5 stores a table file such as a data table 11 illustrated in FIG. 5.

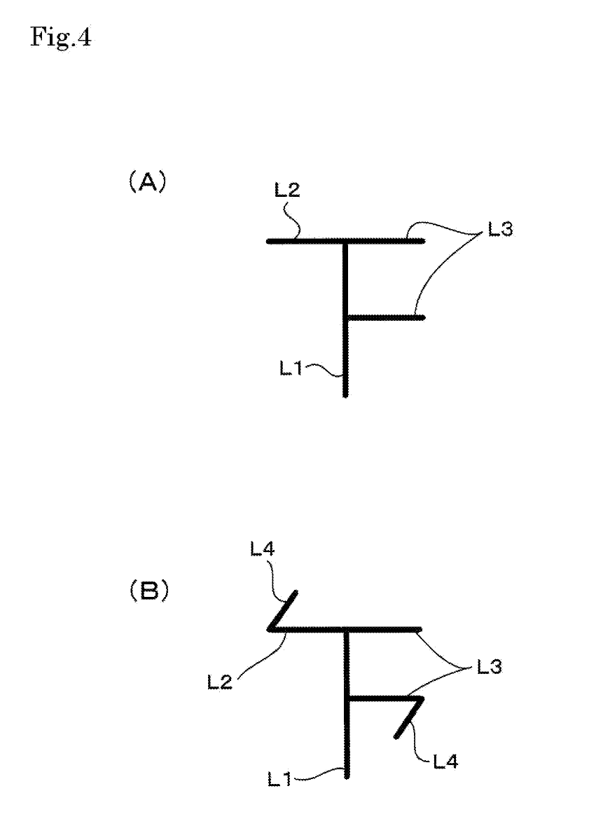

In the data table 11, operations related to the combined detection information 8 are systematized with operation symbols and the data 9 corresponding to each combined detection information 8 is stored through the operation symbols. The operation symbols illustrated in FIG. 4 represent the images of the turning-on operation of the temporary input switches 1 and the actual input switches 2 using plural straight lines.

The operation symbols will be specifically described. The operation symbols represent a first the turning-on operation of the temporary input switches 1 by a straight line L2 extending to the left side and represent a first turning-on operation of the actual input switches 2 by a straight line L3 extending to the right side, from only one vertical straight line L1. The operation symbols represent a second turning-on operation of the temporary input switches 1 or the actual input switches 2 by a straight line L4 extending obliquely from the front end of the straight line L2 or L3. By linking the straight line L4 having the same size to the front end of the straight line L4 in a zigzag way, a third turning-on operation is represented. Likewise, by linking the plural straight lines L4 in a zigzag way, the turning-on operations of the number of times that corresponds to a value obtained by adding 1 to the number of straight lines L4 can be represented.

The straight line L2 extending to the left side is drawn using three divided stages of upper, middle, and lower sides in order to represent a turning-on operation image of each of the three temporary input switches 1a, 1b, 1b, and 1c disposed in one vertical line. That is, a turning-on operation of the temporary input switch 1a is represented by the straight line L2 of the upper stage, an turning-on operation of the temporary input switch 1b is represented by the straight line L2 of the middle stage, and a turning-on operation of the temporary input switch 1c is represented by the straight line L2 of the lower stage.

Likewise, the straight line L3 extending to the right side is drawn using three divided stages of upper, middle, and lower sides in order to represent a turning-on operation image of each of the three actual input switches 2a, 2b, and 2c disposed in one vertical line. That is, a turning-on operation of the actual input switch 2a is represented by the straight line L3 of the upper stage, a turning-on operation of the actual input switch 2b is represented by the straight line L3 of the middle stage, and a turning-on operation of the actual input switch 2c is represented by the straight line L3 of the lower stage.

Therefore, the operation symbol illustrated in FIG. 4(A) represents a series of operations for performing a first turning-on operation on the temporary input switch 1a and performing a first turning-on operation on each of the actual input switch 2a and the actual input switch 2b. Likewise, the operation symbol illustrated in FIG. 4(B) represents a series of operations for performing a second turning-on operation on the temporary input switch 1a, performing a first turning-on operation on the actual input switch 2a, and performing a second turning-on operation on the actual input switch 2b.

Each operation symbol can accurately and simply represent a turning-on operation image of each of the temporary input switches 1 and the actual input switches 2 by each of the straight lines L1 to L4. In the invention, since the combined detection information 8 can be easily systematized using the combinations of the ON state or the OFF state of the independent two systems of the temporary input switches 1 and the actual input switches 2, the turning-on operation of each of the temporary input switches 1 and the actual input switches 2 can be clearly distinguished, systematized, and represented using the operation symbols.

As illustrated in FIG. 5, for example, if the combination of the ON state or the OFF state of the temporary input switches 1 is allocated to consonant data and the combination of the ON state or the OFF state of the actual input switches 2 is allocated to vowel data, a turning-on operation of the temporary input switch 1 related to a consonant can be represented by a left half of the operation symbol and a turning-on operation of the actual input switch 2 related to a vowel can be represented by a right half of the operation symbol. Therefore, the operation symbols can be used like letters. Hereinafter, when the operation symbols are used as the letters, the corresponding letters are called blind touch letters.

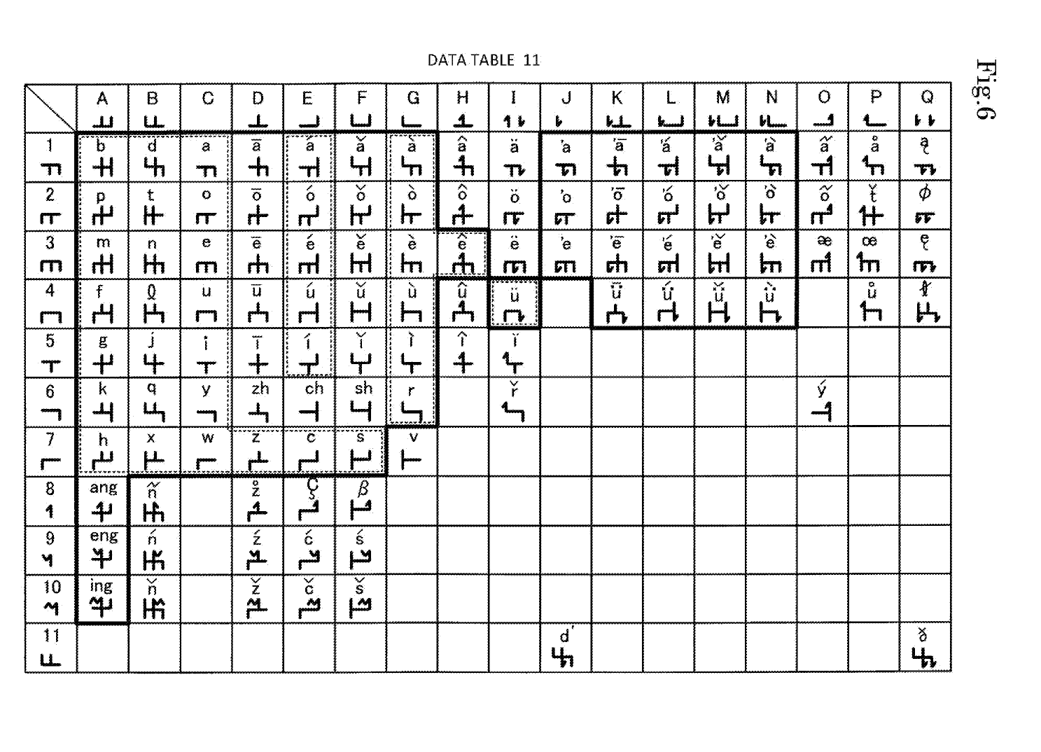

In the operation symbol, the straight line L2 and the straight line L3 may be disposed so as to be in line target with respect to the straight line L1 as the object axis. For example, as illustrated in FIG. 6, the configuration is not excluded in which the operation symbols illustrated in FIGS. 4 and 5 are rotated by 90 degrees in a clockwise direction, the straight line L2 is set as a straight line extending to the upper side, and the straight line L3 is set as a straight line extending to the lower side.

As illustrated in FIG. 6, for example, the alphabet of the European continent or the pinyin symbols of Mainland China can be united to be easily systematized, and can be used as the blind touch letters. Data related to the pinyin symbols is illustrated by a portion surrounded by a thick frame of FIG. 6. Data related to the alphabet is illustrated by a portion surrounded by a dotted-line frame in the portion surrounded by the thick frame and a portion other than the portion surrounded by the thick frame. Therefore, the portion that is surrounded by the dotted-line frame illustrates the data related to the pinyin symbols and the data related to the alphabet at the same time.

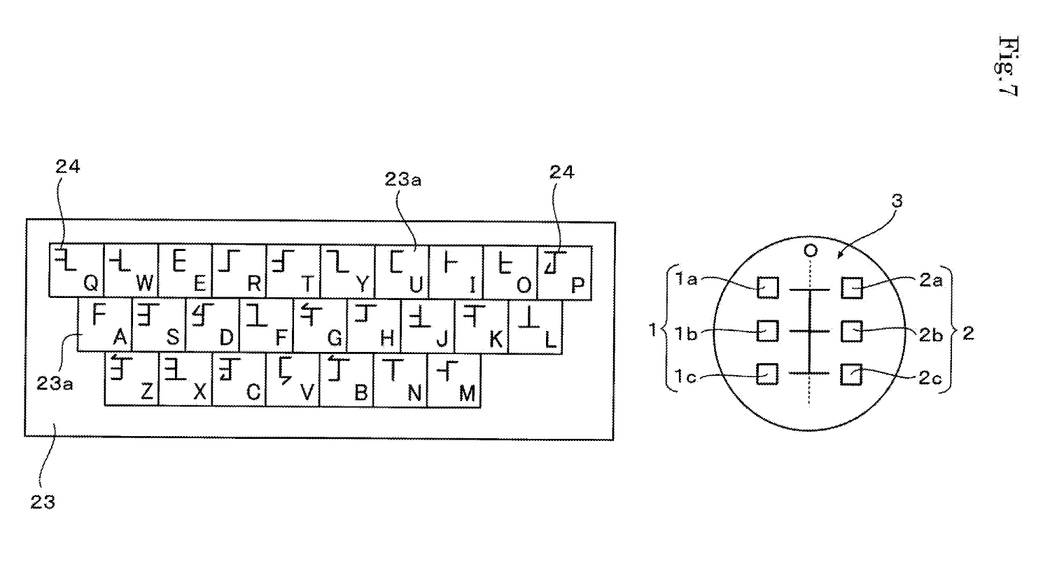

FIG. 7 illustrates an example where the input device according to the present invention is used together with a known keyboard 23. If a blind touch letter 24 is displayed on each key switch 23a of the keyboard 23, an association of each familiar key switch 23a and the blind touch letter 24 becomes clear and the letter input work of an operator and the acquisition of data can be facilitated.

The input work in the input device according to the present invention having the above configuration will be described with reference to FIG. 3. First, according to the operation symbol corresponding to the data 9 which the operator desires to input, the turning-on operation is performed by pressing the predetermined temporary input switch 1 by the predetermined number of times and the turning-off operation is performed by releasing the pressing state. Then, the turning-on operation is performed by pressing the predetermined actual input switch 2 by the predetermined number of times and the turning-off operation is performed by releasing the pressing state (step 1). The operation of the temporary input switch 1 and the operation of the actual input switch 2 are performed together.

In regards to the actual input switches 2, if simultaneous turning-off of all of the actual input switches 2 is detected after detection of the ON state of any actual input switch 2, the combination of the detection information 7 is determined and the combined detection information 8 is generated. For this reason, any actual input switch 2 is held at the turning-on position until the predetermined operation ends, after the turning-on operation of any actual input switch 2 is performed.

When the turning-on operation of the temporary input switches 1 is not needed according to the operation symbol, the operation of only the actual input switches 2 is performed. Since the actual input switches 2 are the simultaneous turning-off objects, the turning-on operation is needed.

In the invention, the number of each of the temporary input switches 1 and the actual input switches 2 of the switch unit 3 is equalized and the temporary input switches 1 and the actual input switches 2 are symmetrically disposed with respect to a line. As a result, the operations of the temporary input switches 1 and the actual input switches 2 can be clearly distinguished and performed and the load of the operator can be alleviated.

Next, the detection information generating unit 4 detects the ON state or the OFF state of the temporary input switches 1 and the ON state or the OFF state of the actual input switches 2 and generates the detection information 7 (detection information 71 and detection information 72) (step 2).

At this time, it is determined whether or not the ON state of any actual input switch 2 is detected (step 3). If the ON state of any actual input switch 2 is detected, it is determined whether or not simultaneous turning-off of all of the actual input switches 2 is detected (step 4). The combination of the detection information 7 is checked to generate the combined detection information 8, only when simultaneous turning-off is detected (step 5).

Therefore, the actual input switches 2 are set to the simultaneous turning-off objects and the temporary input switches 1 are set to the switches other than the simultaneous turning-off objects, so that the combinations of the ON state or the OFF state of the switches of the independent two systems of the actual input switches 2 and the temporary input switches 1 can be realized.

For this reason, the input of the enormous data 9 can be performed by the switch operation divided into two steps, the input work can be significantly facilitated, and the acquisition of the data can be facilitated. For example, as illustrated in FIG. 5, if the combination of the ON state or the OFF state of the temporary input switches 1 is allocated to consonant data and the combination of the ON state or the OFF state of the actual input switches 2 is allocated to vowel data, the input work that is divided into the two steps can be realized and the input work and the acquisition of the data can be facilitated.

Finally, the input determining unit 6 acquires the combined detection information 8 from the detection information generating unit 4, inquires of the storage unit 5 about to the data 9 corresponding to the combined detection information 8, and determines the data 9 to be input (step 6). The input determining unit 6 inputs the determined data 9 to various kinds of computers (step 7) and the input work ends.

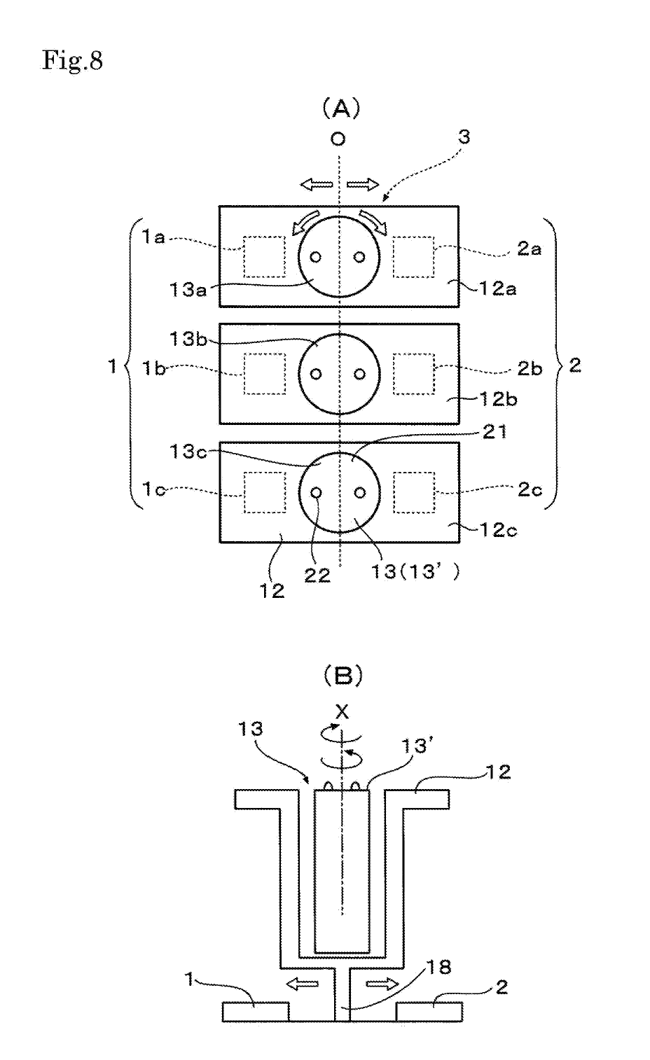

Next, an input/output device according to the present invention will be described on the basis of FIGS. 8 to 13. The components that are common to those of the input device are denoted by the same reference numerals.

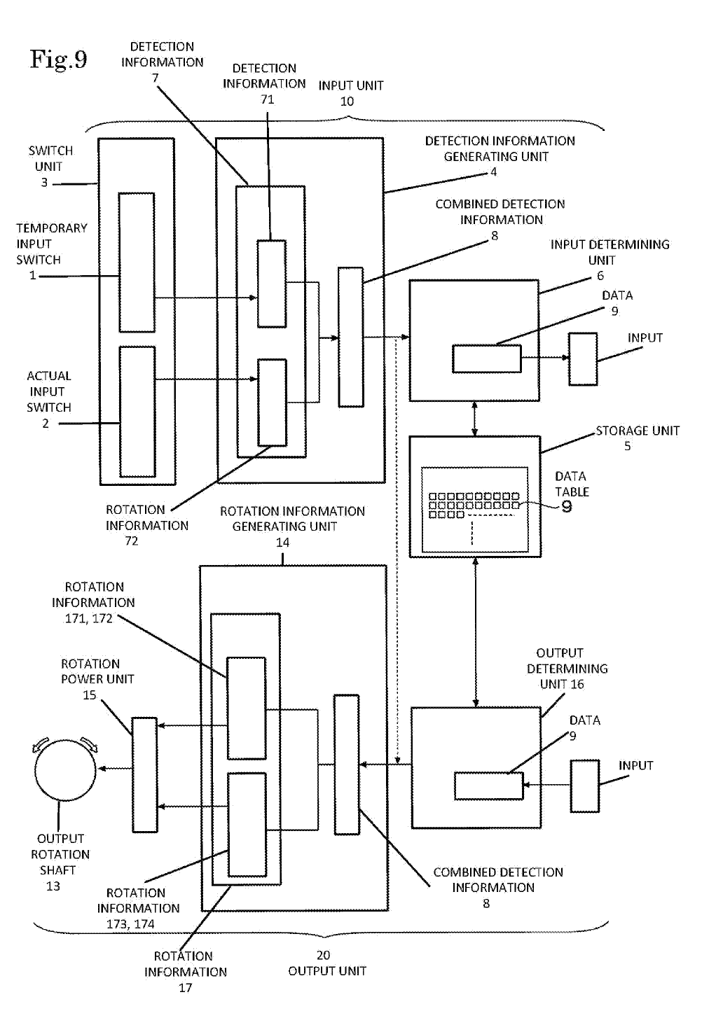

As illustrated in FIGS. 8 and 9, the input/output device according to the present invention includes an input unit 10. The input unit 10 has a switch unit 3 that includes plural temporary input switches 1 and plural actual input switches 2 to be the same number and to be in line target, plural operation units 12 that reciprocally move between the temporary input switches 1 and the actual input switches 2 of the switch unit 3 to be in line target, that is, the temporary input switches 1 and the actual input switches 2 facing each other and perform the turning-on/turning-off operations on the temporary input switches 1 and the actual input switches 2, a detection information generating unit 4 that detects the ON state or the OFF state of each temporary input switch 1 and each actual input switch 2 of the switch unit 3, combines detected information 7, and generates combined detection information 8, a storage unit 5 that stores data 9 corresponding to each combined detection information 8, and an input determining unit 6 that acquires the combined detection information 8 from the detection information generating unit 4, associates the combined detection information 8 with the data 9 stored in the storage unit 5, and determines the data 9 to be input.

In addition, the input/output device includes an output unit 20. The output unit 20 has an output rotation shaft 13 that performs left rotation, right rotation, rotation stop around an axis line X crossing a ventral surface of a fingertip of an operator in each operation unit 12, an output determining unit 16 that acquires data 9 from the outside, associates the data 9 with the data 9 stored in the storage unit 5, and determines the combined detection information 8 to be output, a rotation information generating unit 14 that generates rotation information 17 of the output rotation shaft 13 based on the combined detection information 8 acquired from the output determining unit 16, and a rotation power unit 15 that acquires the rotation information 17 from the rotation information generating unit 14 and causes the left rotation, the right rotation, and the rotation stop of the output rotation shaft 13.

The operation unit 12 and the output rotation shaft 13 are disposed on the surface side of the casing and the switch unit 3, the detection information generating unit 4, the storage unit 5, the input determining unit 6, the rotation information generating unit 14, the rotation power unit 15, and the output determining unit 16 are disposed on the inner side of the casing.

As illustrated in FIGS. 8(A) and (B), the three operation units 12 (12a, 12b, and 12c) are provided to reciprocally move between the temporary input switches 1 (1a, 1b, and 1c) and the actual input switches 2 (2a, 2b, and 2c) facing each other and turning-on/turning-off operations of the temporary input switches 1 and the actual input switches 2 are performed by the operation shaft 18 of the operation unit 12.

Similarly to a known slide switch, the operation unit 12 is held by the elastic biasing unit at the intermediate position between the temporary input switch 1 and the actual input switch 2 facing the temporary input switch 1. The operation unit 12 is slid to the side of the temporary input switch 1 (left side in the drawings) with a finger and a turning-on operation of the temporary input switch 1 is performed. If the finger is released, the operation unit 12 is automatically returned to the intermediate position and a turning-off operation of the temporary input switch 1 is performed. Likewise, the operation unit 12 is slid to the side of the actual input switch 2 (right side in the drawings) with the finger and a turning-on operation of the actual input switch 2 is performed. If the finger is released, the operation unit 12 is automatically returned to the intermediate position and a turning-off operation of the actual input switch 2 is performed.

Similarly to the known key switch, the temporary input switches 1 and the actual input switches 2 reciprocally move between the turning-off position of the upper limit and the turning-on position of the lower limit. The temporary input switches 1 and the actual input switches 2 are held at the turning-off position by the elastic biasing unit at the time of a normal operation and move to the turning-on position at the time of a pressing operation by the operation shaft 18. If the pressing state by the operation shaft 18 is released, the temporary input switches 1 and the actual input switches 2 are automatically returned to the turning-off position by the elastic biasing unit.

The temporary input switches 1, the actual input switches 2, and the operation units 12 are not limited to the above structure. If the turning-on/turning-off operations can be performed by the operation shaft 18 of the operation unit 12, any form may be used. For example, the turning-on/turning-off operations can be performed by supplying or not supplying power to the temporary input switches 1 and the actual input switches 2 using the operation shaft 18, and any structure may be applied according to the implementation.

In the invention, the number of each of the temporary input switches 1, the actual input switches 2, and the operation units 12 is not limited to three. It should be sufficient that the temporary input switches 1 and the actual input switches 2 may be plural in the same number and disposed so as to be symmetric with respect to a line.

In the input unit 10, since the configuration other than the operation unit 12 and the input work are the same as those of the input device described above, the description of the input device is adopted in this case.

Hereinafter, the output work will be described while each configuration of the output unit 20 is described.

Each of the output rotation shafts 13 (13a, 13b, and 13c) is provided in the center portion of each of the operation units 12 (12a, 12b, and 12c) and performs the left rotation, the right rotation, and the rotation stop by the rotation power unit 15 around the axis line X crossing the ventral surface of the fingertip of the operator, and the operator recognizes the left rotation, the right rotation, or the rotation stop of the output rotation shaft 13 through a sense of touch and the data 9 is output.

The front end face 13′ of the output rotation shaft 13 is flush with the surface of the operation unit 12 or protrudes from the surface of the operation unit 12. The front end face 13′ of the output rotation shaft 13 is provided with a concave portion 21 and a convex portion 22, the sense of touch of the operator is raised by the concave portion 21 and the convex portion 22, and the operator can clearly recognize the number of left and right rotations of the output rotation shaft 13 or the rotation stop thereof.

The concave portion 21 and the convex portion 22 are formed such that the shape of a rotation stop state of the output rotation shaft 13 and the shape of a state where the output rotation shaft 13 is rotated by 1/n to the left side from the rotation stop state become the same, and such that the shape of the rotation stop state and the shape of a state where the output rotation shaft 13 is rotated by 1/n to the right side from the rotation stop state become the same, that is, the shape of the rotation stop state of the output rotation shaft 13 and the shape of a state where the output rotation shaft 13 is rotated by 1/n to the left side or the right side from the rotation stop state become the same. For this reason, the operator can recognize the left rotation, the right rotation, or the rotation stop by only 1/n rotation of the output rotation shaft 13.

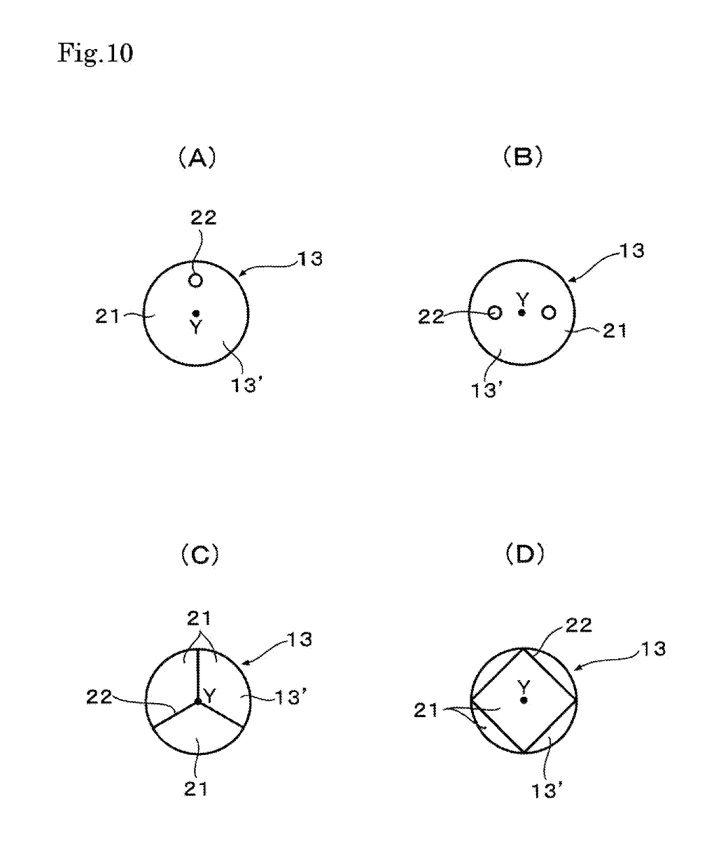

For example, when n is 1, that is, when the concave portion 21 and the convex portion 22 are formed such that the shape of the rotation stop state, the shape of a state where the output rotation shaft 13 is rotated by 1/1 (360 degrees) to the left side from the rotation stop state, and the shape of a state where the output rotation shaft 13 is rotated by 1/1 to the right side from the rotation stop state become the same, as illustrated in FIG. 10(A), one convex portion 22 is formed in the front end face 13′ at an interval from an crossing point Y of the axis line X and the front end face 13′ of the output rotation shaft 13 and the other portion of the front end face 13′ is used as the concave portion 21. Likewise, when n is 2, that is, when the concave portion 21 and the convex portion 22 are formed such that the shape of the rotation stop state, the shape of a state where the output rotation shaft 13 is rotated by ½ (180 degrees) to the left side from the rotation stop state, and the shape of a state where the output rotation shaft 13 is rotated by ½ to the right side from the rotation stop state become the same, as illustrated in FIG. 10(B), the two convex portions 22 that are disposed so as to be in line target with respect to the crossing point Y are formed in the front end face 13′ and the other portion of the front end face 13′ is used as the concave portion 21. Likewise, when n is 3, that is, when the concave portion 21 and the convex portion 22 are formed such that the shape of the rotation stop state, the shape of a state where the output rotation shaft 13 is rotated by ⅓ (120 degrees) to the left side from the rotation stop state, and the shape of a state where the output rotation shaft 13 is rotated by ⅓ to the right side from the rotation stop state become the same, as illustrated in FIG. 10(C), the three convex portions 22 are formed in the front end face 13′ at an interval of equal angles in a circumferential direction from the crossing point Y and the other portion of the front end face 13′ is used as the concave portion 21. Likewise, when n is 4, that is, when the concave portion 21 and the convex portion 22 are formed such that the shape of the rotation stop state, the shape of a state where the output rotation shaft 13 is rotated by ¼ (90 degrees) to the left side from the rotation stop state, and the shape of a state where the output rotation shaft 13 is rotated by ¼ to the right side from the rotation stop state become the same, as illustrated in FIG. 10(D), the four convex portions 22 are formed in the front end face 13′ at an interval of equal angles in a circumferential direction from the crossing point Y and the other portion of the front end face 13′ is used as the concave portion 21.

However, n is not limited to 1 to 4 and may be an integer of 5 or more. The shapes of the concave portion 21 and the convex portion 22 are not limited to the form illustrated in FIG. 10 and any form may be used, as long as the concave portion 21 and the convex portion 22 are formed such that the shape of the rotation stop state of the output rotation shaft 13 and the shape of a state where the output rotation shaft 13 is rotated by 1/n to the left side from the rotation stop state become the same and the shape of the rotation stop state of the output rotation shaft 13 and the shape of a state where the output rotation shaft 13 is rotated by 1/n to the right side from the rotation stop state become the same.

As illustrated in FIG. 9, the output determining unit 16 acquires the data 9 corresponding to the data 9 acquired from the outside, from the storage unit 5, and transmits the combined detection information 8 related to the data 9 to the rotation information generating unit 14.

The rotation information generating unit 14 generates the rotation information 17 from the combined detection information 8 acquired from the output determining unit 16. In the invention, as illustrated by a dotted line in FIG. 9, the rotation information generating unit 14 may acquire the combined detection information 8 directly from the detection information generating unit 4 of the input unit 10 of the self device or another device.

Specifically, the rotation information generating unit 14 generates the rotation information 17 (171) of one of the left and right rotations of the output rotation shaft 13 from the turning-on detection information 7 (71) of the temporary input switch 1 in the combined detection information 8, generates the rotation information 17 (173) of the other one of the left and right rotations of the output rotation shaft 13 based on the turning-on detection information 7 (72) of the actual input switch 2, generates the rotation information 17 (172) of the rotation stop of the output rotation shaft 13 based on the turning-off detection information 7 (71) of the temporary input switch 1, generates the rotation information 17 (174) of the rotation stop based on the turning-off detection information 7 (72) of the actual input switch 2, and generates the rotation information 17 (174) of the simultaneous rotation stop of all of the output rotation shafts 13 based on the simultaneous turning-off detection information 7 (72) of all of the actual input switches 2. In order to simplify the description, in the following description, the rotation according to the rotation information 171 related to the turning-on detection of the temporary input switch 1 is set as the left rotation and the rotation according to the rotation information 173 related to the turning-on detection of the actual input switch 2 is set as the right rotation.

Next, the rotation information generating unit 14 transmits the rotation information 17 (171, 172, 173, and 174) to the rotation power unit 15.

Each rotation power unit 15 is provided with respect to each output rotation shaft 13, the left rotation and the rotation stop of the output rotation shaft 13 are made on the basis of the rotation information 171 and 172, that is, the rotation information 171 and 172 related to the turning-on/turning-off states of the temporary input switches 1, and the right rotation and the rotation stop of the output rotation shaft 13 are made on the basis of the rotation information 173 and 174, that is, the rotation information 173 and 174 related to the turning-on/turning-off states of the actual input switches 2. A known servo motor is used as the rotation power unit 15 and the left and right rotations, the rotation stop, and the rotation speed of the output rotation shaft 13 are controlled.

The rotation power unit 15 causes the left rotation and the rotation stop of the output rotation shaft 13 of the operation unit 12 that performs the turning-on/turning-off operations of the temporary input switches 1 corresponding to the combined detection information 8. When the turning-on detection information 7 (71) of the temporary input switches 1 indicates the plural turning-on operations of the temporary input switches 1, the rotation power unit 15 causes the left rotation by the number of times. The left rotation includes the case of 1/n rotation as described above.

The rotation power unit 15 causes the right rotation and the rotation stop of the output rotation shaft 13 of the operation unit 12 that performs the turning-on/turning-off operations of the actual input switches 2 corresponding to the combined detection information 8. When the turning-on detection information 7 (72) of the actual input switches 2 indicates the plural turning-on operations of the actual input switches 2, the rotation power unit 15 causes the right rotation by the number of times. The right rotation includes the case of 1/n rotation as described above.

As a specific output operation, first, the left rotation of the output rotation shaft 13 is made by the rotation power unit 15 on the basis of the rotation information 171 and 172, and the stop of the left rotation is made after the left rotation by the predetermined number of times. When the left rotation of the plural output rotation shafts 13 needs to be made, the rotation of the corresponding output rotation shafts 13 simultaneously start. The left rotation and the stop of the left rotation of the corresponding output rotation shafts 13 may be sequentially made.

After the stop of the left rotation, the right rotation of the output rotation shaft 13 is made by the rotation power unit 15 on the basis of the rotation information 173 and 174, and the stop of the right rotation is made after the right rotation by the predetermined number of times. In the output rotation shaft 13 where the left rotation is not needed, the stop of the left rotation of the other output rotation shafts 13 by the rotation power unit 15 does not need to be waited, the right rotation may be made from the beginning, and the stop of the right rotation may be made after the right rotation by the predetermined number of times. When all of the output rotation shafts 13 do not need the left rotation, the right rotation of the output rotation shaft 13 is made from the beginning by the rotation power unit 15, and the stop of the right rotation is made after the right rotation by the predetermined number of times. When the right rotation of the plural output rotation shafts 13 needs to be made, the rotation power unit 15 adjusts the rotation speed and causes the rotation stop, such that the rotation of all of the output rotation shafts 13 is simultaneously stopped, on the basis of the rotation information 17 (174) of the simultaneous rotation stop of all of the output rotation shafts 13. The operator recognizes a separator of the letters through the simultaneous rotation stop (simultaneous stop of the right rotation).

As described above, the combinations of the rotations of the independent two systems and the stops of the rotations can be realized by the combination of the left rotation or the stop of the left rotation of the output rotation shaft 13 and the combination of the right rotation or the stop of the right rotation of the output rotation shaft 13. As a result, the output of the enormous data 9 can be performed by the rotation divided into two steps, the output work can be significantly facilitated, and the data can be securely output to the operator.

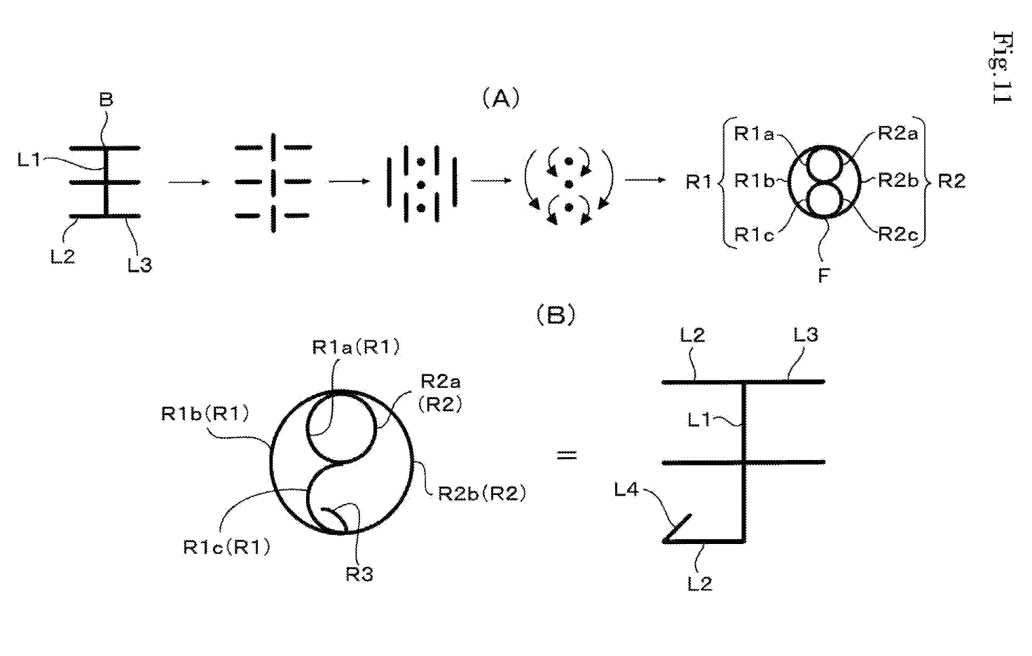

The series of outputs, that is, the images that are output by the left rotation, the right rotation, and the rotation stop of the output rotation shaft 13 can be systematized by tactile symbols. The tactile symbols are obtained by deforming the operation symbols on the basis of the rotation images at the time of the output and representing the symbols with plural arc lines. That is, in the tactile symbols, the straight line L2 that extends to the left side in the operation symbols is changed to a semi-circular arc line R1 disposed on the left side in the tactile symbols and the straight line L3 that extends to the right side in the operation symbols is changed to a semi-circular arc line R2 disposed on the right side in the tactile symbols, through the change illustrated in FIG. 11(A).

Specifically, the semi-circular arc line R1 sets a small-diameter semi-circular arc line of the upper stage as R1a and corresponds to the straight line L2 of the upper stage of the operation symbol, sets a small-diameter semi-circular arc line of the lower stage as R1c and corresponds to the straight line L2 of the lower stage of the operation symbol, and sets a large-diameter semi-circular arc line as R1b and corresponds to the straight line L2 of the middle stage of the operation symbol. Likewise, the semi-circular arc line R2 sets a small-diameter semi-circular arc line of the upper stage as R2a and corresponds to the straight line L3 of the upper stage of the operation symbol, sets a small-diameter semi-circular arc line of the lower stage as R2c and corresponds to the straight line L3 of the lower stage of the operation symbol, and sets a large-diameter semi-circular arc line as R2b and corresponds to the straight line L3 of the middle stage of the operation symbol.

The arc line R3 illustrated in FIG. 11(B) corresponds to the straight line L4 that extends obliquely in the operation symbol. By linking the arc line R3 with the lower end of any semi-circular arc line R1 or R2 inwardly or outwardly, the rotation of the plural number of times can be represented.

Therefore, the semi-circular arc line R1 that is disposed on the left side represents the left rotation image of each of the three output rotation shafts 13a, 13b, and 13c that are disposed in one vertical line. That is, the left rotation of the output rotation shaft 13a is represented by the small-diameter semi-circular arc line R1a of the upper stage, the left rotation of the output rotation shaft 13b is represented by the large-diameter semi-circular arc line R1b, and the left rotation of the output rotation shaft 13c is represented by the small-diameter semi-circular arc line R1c of the lower stage.

Likewise, the semi-circular arc line R2 that is disposed on the right side represents the right rotation image of each of the three output rotation shafts 13a, 13b, and 13c that are disposed in one vertical line. That is, the right rotation of the output rotation shaft 13a is represented by the small-diameter semi-circular arc line R2a of the upper stage, the right rotation of the output rotation shaft 13b is represented by the large-diameter semi-circular arc line R2b, and the right rotation of the output rotation shaft 13c is represented by the small-diameter semi-circular arc line R2c of the lower stage.

For example, the tactile symbol illustrated at the left side of FIG. 11(B) represents a series of rotations where the left rotation of each of the output rotation shafts 13a and 13b is performed once, the left rotation of the output rotation shaft 13c is performed two times, and the rotation of each of the output shafts 13a, 13b, and 13c is stopped, and the right rotation of each of the output rotation shafts 13a and 13b is performed once and the rotation of the output rotation shafts 13a and 13b is simultaneously stopped.

Therefore, the tactile symbols can accurately and simply represent the output image of each data 9, that is, the image of the left rotation or the right rotation of the output rotation shaft 13 and the number of times of rotation by the semi-circular arc lines R1 and R2 and the arc line R3. For this reason, the tactile symbols can be used like the letters. Hereinafter, the letters are called finger sense letters, when the tactile symbols are used as the letters.

In the tactile symbols, in order to represent the case where the stop of the left rotation of the other output rotation shafts 13 does not need to be waited with respect to the output rotation shaft 13 not needing the left rotation as described in the output operation and the right rotation is made from the beginning, this case may be distinguished with the case where a vertical straight line is added to the center of the tactile symbol, the stop of the left rotation of the other output rotation shafts 13 is waited, and the right rotation is made.

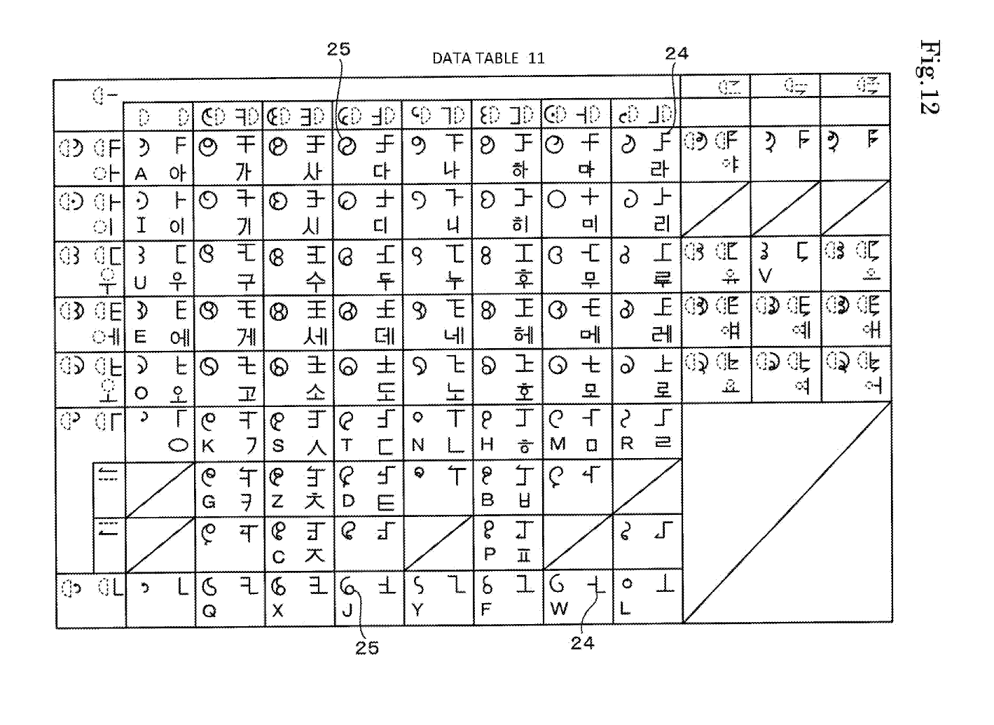

FIG. 12 illustrates the case where Hangul letters are systematized and the operation symbols and the tactile symbols are represented in parallel, different from FIG. 5 or 6. In this case, the operation symbols and the tactile symbols can be easily systematized and the operation symbols can be used as the blind touch letters 24 and the tactile letters can be used as the finger sense letters 25.

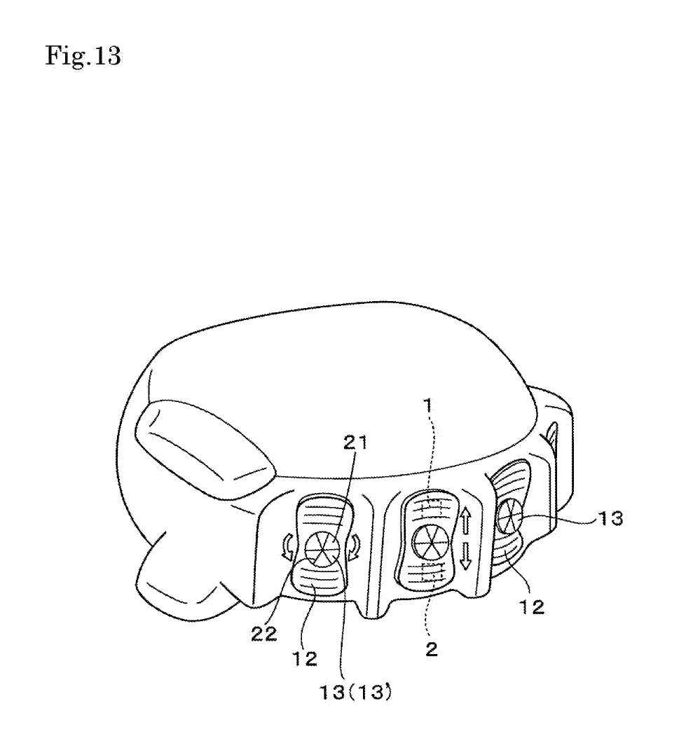

Finally, FIG. 13 illustrates a usage example of the input/output device according to the present invention. That is, FIG. 13 illustrates an example of the case where the four temporary input switches 1 and the four actual input switches 2 are disposed so as to be in line target in a vertical direction, the operation units 12 are disposed between the temporary input switches 1 and the actual input switches 2 disposed so as to be in line target to reciprocally move in the vertical direction, and the output rotation shafts 13 are provided in the operation units 12. The casing is configured to be gripped by one hand, thereby improving operability.

If the input/output device according to the present invention is connected to a communication network, for example, a wireless LAN, the operator can converse with the separated counterpart using only a finger. In particular, if a handicapped person who has difficulty in conversation due to a hearing defect or a speech defect uses the input/output device, the input/output device can be effectively used.

### REFERENCE SIGNS LIST

1: temporary input switch

1a: top temporary input switch

1b: middle temporary input switch

1c: bottom temporary input switch

2: actual input switch

2a: top actual input switch

2b: middle actual input switch

2c: bottom actual input switch

3: switch unit

4: detection information generating unit

5: storage unit

6: input determining unit

7, 71, 72: detection information

8: combined detection information

9: data

10: input unit

11: correspondence table

12: operation unit

12a: top operation unit

12b: middle operation unit

12c: bottom operation unit

13: output rotation shaft

13a: top output rotation shaft

13b: middle output rotation shaft

13c: bottom output rotation shaft

14: rotation information generating unit

15: rotation power unit

16: output determining unit

17: rotation information

171: rotation information of one (left rotation) of left and right rotations

172: rotation information of rotation stop of one (left rotation) of left and right rotations

173: rotation information of the other one (right rotation) of left and right rotations

174: rotation information of rotation stop of the other one (right rotation) of left and right rotations or simultaneous rotation stop of all of output rotation shafts

18: operation shaft

20: output unit

21: concave portion

22: convex portion

23: keyboard

23a: key switch

24: blind touch letter

25: finger sense letter

L1: vertical straight line

L2: horizontal straight line extending to the left side

L3: horizontal straight line extending to the right side

L4: straight line extending obliquely

R1: semi-circular arc line disposed on the left side

R1a: semi-circular arc line corresponding to L2 of upper stage of operation symbol

R1b: semi-circular arc line corresponding to L2 of middle stage of operation symbol

R1c: semi-circular arc line corresponding to L2 of lower stage of operation symbol

R2: semi-circular arc line disposed on right side

R2a: semi-circular arc line corresponding to L3 of upper stage of operation symbol

R2b: semi-circular arc line corresponding to L3 of middle stage of operation symbol

R2c: semi-circular arc line corresponding to L3 of lower stage of operation symbol

R3: arc line corresponding to L4

X: axis line crossing ventral surface of fingertip of operator

Y: crossing point of axis line and front end face of output rotation shaft

1. An input device comprising:
a switch unit that includes a plurality of temporary input switches and a plurality of actual input switches;
a detection information generating unit that detects an ON state or an OFF state of each temporary input switch and each actual input switch of the switch unit, combines detected information, and generates combined detection information;
a storage unit that stores data corresponding to each combined detection information; and
an input determining unit that acquires the combined detection information from the detection information generating unit, associates the acquired combined detection information with data stored in the storage unit, and determines data to be input,
wherein the combination of the detection information is determined only when the detection information generating unit detects the ON state of any actual input switch and detects simultaneous turning-off of all of the actual input switches, and
wherein the number of each of the temporary input switches and the actual input switches of the switch unit is equalized and the temporary input switches and the actual input switches are disposed so as to be symmetric with respect to a line.

2. An input/output device comprising:
an input unit that has a switch unit that includes a plurality of temporary input switches and a plurality of actual input switches to be the same number and to be disposed so as to be symmetric with respect to a line, a plurality of operation units that reciprocally move between the temporary input switches and the actual input switches of the switch unit to be disposed so as to be symmetric with respect to a line and perform the turning-on/turning-off operations on the temporary input switches and the actual input switches, a detection information generating unit that detects the ON state or the OFF state of each temporary input switch and each actual input switch of the switch unit, combines detected information, and generates combined detection information, a storage unit that stores data corresponding to each combined detection information, and an input determining unit that acquires the combined detection information from the detection information generating unit, associates the combined detection information with the data stored in the storage unit, and determines data to be input, and determines the combination of the detection information only when the detection information generating unit detects the ON state of any actual input switch and detects simultaneous turning-off of all of the actual input switches; and
an output unit that has an output rotation shaft that performs left rotation, right rotation, rotation stop about an axis line crossing a ventral surface of a fingertip of an operator in each operation unit, an output determining unit that acquires data from the outside, associates the data with the data stored in the storage unit, and determines the combined detection information to be output, a rotation information generating unit that generates rotation information of the output rotation shaft from the combined detection information acquired from the output determining unit, and a rotation power unit that acquires the rotation information from the rotation information generating unit and causes the left rotation, the right rotation, and the rotation stop of the output rotation shaft, wherein the rotation information generating unit generates rotation information of one of the left and right rotations from the turning-on detection information of the temporary input switches in the combined detection information, generates rotation information of the other one of the left and right rotations from the turning-on detection information of the actual input switches, generates rotation information of the rotation stop from turning-off detection information of the temporary input switches, generates rotation information of the rotation stop from turning-off detection information of the actual input switches, generates rotation information of simultaneous rotation stop of all of output rotation shafts from simultaneous turning-off detection information of all of the actual input switches, and generates the rotation information.

3. The input/output device according to claim 2,
wherein an uneven portion that raises a sense of touch with a ventral surface of a fingertip of an operator is formed on a front end face of the output rotation shaft, and the uneven portion is formed such that the shape of a rotation stop state of the output rotation shaft and the shape of a state in which the output rotation shaft is rotated by 1/n to the left side from the rotation stop state become the same and the shape of the rotation stop state and the shape of a state in which the output rotation shaft is rotated by 1/n to the right side from the rotation stop state become the same.
